(19) United States
(12) Patent Application Publication
(10) Pub. No.: US 2006/0201412 A1
(43) Pub. Date: Sep. 14, 2006

(54) Method of making highly uniform low-stress single crystals with reduced scattering

(76) Inventors: Christian Poetisch, Jena (DE); Gunther Wehrhahn, Jena (DE); Lutz Parthier, Kleinmachnow (DE); Hans-Joerg Axmann, Jena (DE); Joerg Staeblein, Jena (DE)

Correspondence Address: STRIKER, STRIKER & STENBY, 103 EAST NECK ROAD, HUNTINGTON, NY, 11743, US

(21) Appl. No.: 11/366,634

(22) Filed: Mar. 2, 2006

(30) Foreign Application Priority Data
Mar. 8, 2005 (DE) 10 2005 010 654.4
Mar. 24, 2005 (DE) 10 2005 013 876.4

(51) Int. Cl. C30B 15/00; C30B 21/06; C30B 27/02; C30B 28/10; C30B 30/04

(52) U.S. Cl. 117/13

(57) ABSTRACT

The method produces highly uniform, low-stress single crystals, especially of calcium fluoride. A single crystal drawn from a melt apparatus with a suitable process is cooled and subsequently subjected to a tempering step. The method is characterized by rapid cooling in a temperature range between less than or equal to 1300° C. and greater than or equal to 1050° C. with a cooling rate of greater than or equal to 10 K/h and preferably less than or equal to 60 K/h.

### BACKGROUND OF THE INVENTION

1. The Field of the Invention

The present invention relates to methods of making low-stress, highly homogeneous single crystals.

2. The Background of the Invention

Single crystals are required as an alternative to quartz glass for optical components in DUV photolithography. They are commonly used as lens or prism material. They are also used for optical imaging of fine structures in integrated circuits, on computer chips and/or on wafers coated with photo lacquer coatings.

Calcium fluoride single crystals are preferred for use because they have a high transmission far into the UV range and thus are suitable for use in excimer lasers. These lasers permit lithographic manufacture of chip structures with a width of less than 100 nm at these wavelengths (KrF: 248 nm; ArF: 193 nm; F₂: 157 nm).

Methods for making single crystals and suitable optical elements from. them are known. In principle they can be grown from the gas phase, the melt, solution and even from the solid phase by re-crystallization or solid body diffusion. However single crystals are manufactured industrially by solidification from a melt. For example, the Czochralski method, the Bridgman-Stockbarger method or the Vertical gradient freezing method have been used for industrial manufacturing of single crystals. In these methods an appropriate crystal raw material mass is melted and maintained at a temperature above its melting point. The melted mass is usually brought into contact with a seed crystal, on which the melted material crystallizes out little by little, whereby the crystal grows, and indeed oriented in one of the orientations of the seed crystal. Subsequently the single crystal obtained in this way is cooled to room temperature.

The axial temperature gradient required for the crystal growth process and the temperature gradients occurring during the cooling of the crystal lead to stresses in the crystal, which can lead to stress birefringence. Conventionally the stress birefringence occurring during manufacture moves into a range of from 5 to 20 nm/cm, which is too large for the later applications in DUV photo-lithography. The single crystal is later cut and further processed by mechanical operations, such as milling and polishing, to make optical elements, which can still further increase already high stress birefringence.

The formation of stresses in the crystal can be reduced until at a certain degree by the most careful and precise temperature control during the crystallization process and by slow cooling. However this sort of single crystal made in this way still does not fulfill the requirements for the most recent applications in DUV photolithography.

For these reasons attempts were made to improve the optical properties of single crystals made in this way by subsequent cooling over a long time interval to a temperature below the melting point.

The heating called “tempering” leads to a disordering of the atoms in the crystal lattice by relaxation and diffusion processes, whereby both mechanical stresses and also crystal defects are eliminated or at least reduced. Those changes are also accompanied by a reduction of the stress birefringence and slip bands and an increase in the refraction index uniformity of the single crystal.

This process is e.g. disclosed in EP-A-939 147, which describes the making of a calcium fluoride crystal, especially for photolithography. Large single crystals were put in a closed container and heated under vacuum to a first temperature, which was in a range of 1020° C. to 1150° C. and after that they were cooled with a cooling speed of at least 1.2-2 K/h to a temperature of 600-900° C. in a first stage. After that a cooling to room temperature with a cooling speed of at most 5 K/h occurred. In a preferred embodiment the tempering is performed in a fluorine-gas-containing atmosphere and under a protective gas.

Stress birefringence and slip bands are largely reduced with this sort of process so that the single crystals made in this way satisfy the requirements for DUV photolithography. For this purpose it is assumed however that a certain cooling speed is not exceeded during cooling of the single crystal immediately after the crystallization process, which would limit the stresses produced by the cooling from the start of the process to a certain extent.

However new problems are produced by the slow cooling: Crystalline CaF₂ has increased solubility for elementary oxygen at elevated temperatures. Some dissolved oxygen still remains in the finished single crystals in spite of the processing under vacuum and use of scavenger additives, which react with oxygen to form easily volatilize oxides, which evaporate from the melt.

On cooling of the grown crystal the dissolved oxygen diffuses in the crystal lattice and collects with additional oxygen to form oxide clusters.

Should these cluster regions exceed a certain critical size they act as scattering centers, at which so-called Raleigh scattering can occur. This sort of scattering is produced by particles with a diameter of greater than or equal to λ/20 (also at least a twentieth of the wavelength of light). Scattering particles with a diameter of 9.7 nm are sufficiently large theoretically to produce light scattering in a calcium fluoride single crystal at wavelengths of 193 nm (ArF excimer laser). In contrast scattering particles with a diameter of 7.85 nm are sufficiently large theoretically to produce light scattering at wavelengths of 157 nm (F₂ excimer laser).

Similar problems arise due to residual water dissolved in the crystal lattice in spite of vacuum pre-treatment and pre-tempering of the melt material, so that under certain circumstances the residual water can react with calcium to form Ca(OH)₂ and/or CaO.

### SUMMARY OF THE INVENTION

It is an object of the present invention to provide a method of making an improved single crystal, especially a calcium fluoride single crystal, which has reduced small stresses and thus a smaller fraction of slip bands and a higher index of refraction uniformity and which has a reduced smaller amount of scattering, a smaller amount of schlieren and of small-angle-grain boundaries.

According to the invention the method of making a highly uniform, low-stress, large-volume single crystal, especially of calcium fluoride (CaF₂), comprises the steps of:
a) growing the single crystal from a melt;
b) cooling the single crystal; and
c) subsequently tempering the single crystal;
wherein the cooling of the single crystal after growing occurs in a temperature range between 1300° C. and 1050° C. with a cooling rate of at least 10 K/h.

The method according to the invention is characterized by a comparatively rapid cooling after the crystal is grown, i.e. after its crystallization in a temperature range between 1300° C. and 1050° C., i.e. with a cooling speed of at least 10 K/h. This occurs especially in connection with its growth, i.e. in a first cooling stage of the still hot crystal. After the first cooling stage the crystal is preferably no longer heated to temperatures above 1100° C. at subsequent time points and of course neither entirely nor partially. It is especially preferable that the crystal is not heated again to temperatures above 1075° C. and/or 1050° C. after its growth.

It was found experimentally that this temperature region is especially sensitive in regarding to formation of scattering particles, schlieren and small-angle-grain boundaries. The formation of scattering particles and schlieren can be prevented and/or the arising scattering particles can be kept under the critical size for Raleigh scattering by increasing the cooling rate in this range.

At the same time the formation of small-angle-grain boundaries can be reduced and/or totally avoided by the accelerated cooling rate in this temperature range.

Preferably the upper limit of the temperature range, in which cooling is rapid, is below 1200° C., especially below 1185° C., wherein below 1175° C. is especially preferred. The lower limit of this range preferably is above 1050° C., and especially above 1075° C., wherein above 1100° C. is especially preferred. Preferred cooling speeds or rates amount to at least 20 K/h in this temperature range. The preferred maximum cooling rate amounts to 65 K/h, especially a maximum of 50 K/h, but a maximum of 45 K/h and especially a maximum of 40 K/h is especially preferred.

Especially the rapid cooling according to the invention occurs over the entire previously defined temperature range.

According to the invention it was found that this temperature range is especially critical for formation of scattering particles, schlieren and small-angle-grain boundaries. Thus an increased cooling rate can lead to a significant reduction of these phenomena in this temperature range.

The single crystal is especially preferably cooled in the above-described temperature range with a cooling rate of between ≧20 K/h and ≦40 K/h. The formation of scattering particles, schlieren and small-angle-grain boundaries is entirely especially effectively suppressed at these cooling rates.

It has been shown that the higher cooling rate according to the invention indeed promotes formation of thermal stresses as well as a higher dislocation density and formation of slip bands and thus reduces index of refraction uniformity. However it was also found that they can be kept small by a suitable further comparatively slow cooling below the previously defined temperature range in which comparatively rapid cooling takes place.

Thus preferred embodiments of the method according to the invention provided that, after its rapid cooling in connection with crystal growth, the single crystal is cooled at a second cooling rate of less than 10 K/h, preferably less than 5 K/h, in a temperature range below 1075° C. and especially below 1050° C. and/or below 1000° C. until at a temperature of about 900° C. In this way the formation of more extreme thermal stresses in the crystal and the disadvantageous appearance connected with it—in spite of the previously described more rapid cooling rate—can be minimized or kept small.

In spite of these steps the increased cooling rate leads to increased stresses in the single crystal, which causes formation of slip bands and negatively influences index of refraction uniformity of the crystal. These stresses are reduced in a subsequent tempering process. This tempering step can be performed as a process step directly in the melting apparatus or also however as a separate process in a special oven.

The tempering step includes heating the single crystal to a tempering temperature, which is below the melting point of the single crystal.

In a preferred embodiment of the method however it is provided that the tempering step includes heating of the single crystal to a tempering temperature between 1050° C. and 1150° C., if applicable to 1100° C.

It is important that the single crystal is not heated higher than 1150° C., since it was found that temperatures above that surprisingly promote formation of sub-grain structures in the crystal. Furthermore the formation of scattering particles and schlieren can be promoted anew.

It is especially preferred that the single crystal is heated at a heating rate between 5 K/h and 50 K/h at the tempering temperature during the tempering step. Moreover it has proven beneficial to keep the single crystal at the tempering temperature for a time interval of from 24 to 240 h. However shorter or longer tempering time intervals are allowed.

The stresses arising in the crystal are dissipated by relaxation and diffusion process during this holding stage, with the result that the inherent stresses and thus the slip bands are eliminated and the index of refraction uniformity of the crystal is substantially improved.

It is decisive for the success of the tempering step that the single crystal is cooled very slowly again after the heat treatment, in order to avoid promoting the occurrence of thermal stresses again. Thus it is preferable to cool the single crystal at a rate between 0.1 and 1.5 K/h in a temperature range between the tempering temperature and 800° C. depending on the size and orientation of the crystal.

In contrast the single crystal is cooled at a somewhat higher rate, which is preferably in a range of from 0.3 to 3 K/h, in a temperature range below 800° C. Then the single crystal can be cooled to room temperature and/or even to 0° C. or below with this cooling speed and/or rate.

Basically the single crystal is made by the Czochralski method, zone melting method, Bridgman-Stockbarger method or the Vertical gradient freezing method. These methods have proven to be especially suitable for industrial growth of single crystals. However it is likewise conceivable to use another crystal growing method from the state of the art, in which the crystal is grown from the melt.

The optical quality of the manufactured single crystal depends on a series of other factors. Thus it is of decisive importance that the crystal is not contaminated by impurities.

Thus the starting material or raw material used for crystal growth should have an oxygen content of ≦3 ppm and/or a content of transition metals of ≦1 ppm in total. In this way formation of scattering particles can be already reduced already by the selection of suitable starting materials or pre-products.

Alkali and/or alkaline earth halides, and their mixtures, are preferred crystal materials. Fluorides, chlorides and/or bromides are preferred halides, but fluorides are especially preferred. Sodium, potassium and/or lithium are preferred alkali metal ions. Magnesium, calcium, barium and/or strontium are preferred alkaline earth metal ions. Also mixed crystals are preferred. Mixed crystals of the general formulae: BaₓSr₁₋ₓF₂ and BaₓCa₁₋ₓF₂ with x=0 to 1 and BaₓCa₁₋ₓF₂ with x=0.1±0.02 are especially preferred.

Melting apparatuses for crystal growth are frequently equipped with a graphite susceptor for optimum heat transmission. Furthermore graphite resists attack by the forming hydrofluoric acid and thus protects the melt apparatus from corrosion. Also graphite provides a reducing atmosphere during the tempering stage, since it reacts with the residual water present at the existing conditions to form carbon monoxide, carbon dioxide and methane. In this way CaO can be reduced to CaF₂ in the single crystal, which leads to a reduction in the schlieren and—due to reduction of the crystal structural defects—to a reduction of the small-angle-grain boundaries.

For that reason graphite is provided as cladding for the melt apparatus in especially preferred embodiments of the inventive method. Also graphite is additionally preferably added to the single crystal during the tempering. In both cases the graphite with an impurity level of ≦20 ppm is preferably used.

Likewise preferably the gas used in the melting, crystal growing, cooling and/or tempering stages has a purity of ≧99.999%, preferably of 99.9999%, and/or a vacuum with a pressure adjusted to ≦5×10⁻⁶ mbar is used to remove residual moisture from the melting apparatus.

An additional preferred embodiment of the invention provides that the melting, the crystal growing, the cooling and/or the tempering stage is performed in the presence of a scavenger, which is selected from the group consisting of SnF₂, PbF₂, ZnF₂ and XeF₂. The added scavenger reacts with oxygen arising during crystallization partially from the raw materials and partially by oxidation and/or hydrolysis to form easily volatilized oxides, which evaporate at these temperatures.

Likewise gaseous scavengers, such as fluorine gas, mixtures of fluorine gas and inert gas, fluorocarbon gases and fluorohydrocarbon gases and their mixtures with inert gas are suitable. Mixtures of fluorocarbon gases with inert gas with resulting fluorocarbon concentrations of from 1 to 50%, especially from 5 to 30%, are especially preferred. The use of this sort of gas mixture leads—apart from pure inert gas, vacuum or powder scavengers—to improvements of the transmission of the single crystal. Gas and powder scavengers can be used together.

In order to guarantee a high precision in formation of the single crystal and to prevent crystal structural defects as much as possible a growing speed of ≦0.5 mm/h is used during the crystal growth. This appropriately happens by exact adjustment of the temperature during the crystallization process.

The high requirements for crystals that are free of stress are especially fulfilled then when the static temperature gradients in the crystal are reduced as well as the dynamic temperatures gradients by heating and cooling processes. These gradients are caused by spatial temperature distributions in the melt apparatus and/or the tempering oven and likewise can lead to formation of stresses in the crystal. The static temperature gradients can be kept within narrow limits by suitable design of the respective apparatus.

Static temperature gradients ≦0.3 K/cm are adjusted in the single crystal during the cooling and/or tempering stage in further preferred embodiments of the method according to the invention. A static radial temperature gradient of ≦0.013 K/cm and static axial temperature gradient of ≦0.07 K/cm are especially preferred. These values relate to the static temperature gradients in the oven and/or the growing or tempering apparatus.

The invention also comprises a single crystal with a free dislocation density of less than or equal to 2.5×10³/cm³, preferably 2.0×10³/cm³ and especially 1.5×10³/cm³; a small-angle-grain boundaries surface area of less than 2 cm²/cm³, preferably less than 1.5 cm²/cm³ and especially less than 1.0 cm²/cm³; a tilting angle between neighboring grains of less than or equal to 100 arc-sec, especially less than or equal to 80 or 90 arc-sec; a total orientation precision of the single crystal or disk made from it of less than or equal to 8 angular minutes, especially 6 or 7 angular minutes; an index of refraction uniformity for a slab or plate of less than or equal to 2×10⁻⁸, especially ≦1.0 or 1.2×10⁻⁸, after deducting 36 first Zernike coefficients; an average value (RMS value) of stress birefringence of a disk or slab in a 111-direction less than or equal to 0.3 or 0.4 nm/cm and in the 100-direction of less than or equal to 0.6 or 0.7, and especially 0.5 nm/cm, and/or a maximum scattering TS less than or equal to 1.5 or 2×10⁴ according to ISO 13696. The TS means the total scattering and TIS means the total integrated scattering.

Preferably the crystals according to the invention have a diameter of at least 100 mm, especially at least 150 mm, and/or a thickness of at least 20 mm, especially at least 30 mm. A suitable upper limit amounts to at most 400 mm, especially at most 300 mm for the diameter, and at most 150 mm, especially 100 mm, for the thickness. However these maximum values could also be exceeded when necessary.

The present invention also includes optical components and/or electronic components that comprise the single crystals according to the invention. These optical components and/or electronic components comprise lenses, prisms, light-conducting rods, optical components for DUV photolithography, steppers, excimer lasers, wafers, computer chips, integrated circuits and electronic units, which contain these circuits and chips.

### BRIEF DESCRIPTION OF THE DRAWING

The objects, features and advantages of the invention will now be illustrated in more detail with the aid of the following description of the preferred embodiments, with reference to the accompanying figures in which:

FIG. 1 is a graphical illustration showing the changes in temperature occurring during the method for making highly uniform, low-stress single crystals according to the present invention.

### DETAILED DESCRIPTION OF THE INVENTION

In the method of making the single crystal according to the invention the crystal raw material, namely polycrystalline CaF₂, is slowly heated in a melting apparatus from room temperature (10) to about 400° C. and is held at that temperature for a short time, in order to dewater the raw material. After that the temperature is heated to a temperature (12) of 1450° C. over a time interval of 20 hours and held at that temperature for a week, so that the residual dissolved oxygen is removed by scavengers, such as SnF₂, PbF₂, ZnF₂ and XeF₂, which were mixed with the raw material. After a week the melt was subjected to a slow two-week cooling (13) to about 1300° C., so that the desired single crystal is crystallized out from the melt in a known way. The single crystal so obtained is then cooled in a first rapid cooling stage (14) with a cooling rate of 15 K/h to 1000° C., and subsequently cooled to room temperature with a cooling rate of 5 K/h in a second reduced-rate cooling stage (15).

The cooled single crystal is then removed from the melting apparatus and transferred into a tempering oven. Subsequently the single crystal is heated in a heating stage (16) with a heating rate of 10 K/h to a tempering temperature (17) at a level of 1100° C. and held there for 240 h at this temperature, in order to dissipate the stresses in this crystal and thus to decrease the slip bands and to increase the index of refraction uniformity. Thus it is important that the single crystal is not heated to temperatures over 1150° C., since it has been shown that those temperatures promote the formation of a cellular structure in the crystal below the grain boundaries, and permits the formation of scattering sites and schlieren.

Subsequently the single crystal is cooled in a first cooling stage (18) with a first cooling rate of 0.3 K/h to a temperature of 800° C. and then in a second cooling stage (19) with a second cooling rate of 2 K/h to room temperature.

One such CaF₂ single crystal made by the method according to the invention has an index of refraction uniformity of 1.2×10⁻⁸ after deduction of 36 Zernike coefficients. The average value of stress birefringence in the 111-direction is below 0.4 nm/cm and in the 100-direction below 0.7 nm/cm. Also the single crystal has a scattering TS of only less than 2×10⁴.

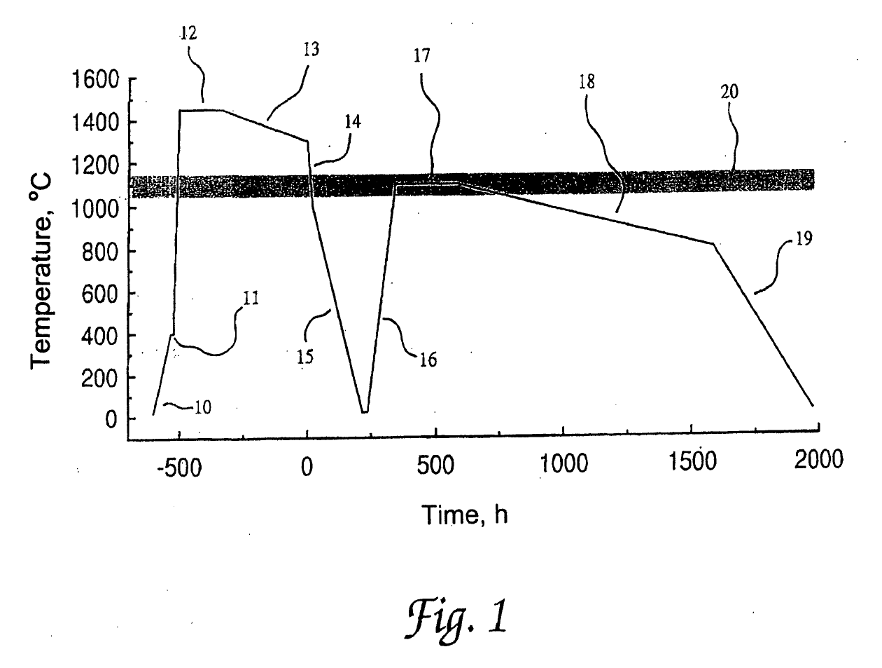

The critical temperature range, which must not be exceeded during tempering and on the other hand must be traversed rapidly in the previous cooling, is shown as a gray bar (20) in FIG. 1.

The disclosures in German Patent Application DE 10 2005 010 654.4 of Mar. 8, 2005 and German Patent Application DE 10 2005 013 876.4 of Mar. 24, 2005 are incorporated here by reference. These German Patent Applications describe the invention described hereinabove and claimed in the claims appended hereinbelow and provide the basis for a claim of priority for the instant invention under 35 U.S.C. 119.

While the invention has been illustrated and described as embodied in a method of making low-stress, highly homogeneous single crystals with reduced scattering, it is not intended to be limited to the details shown, since various modifications and changes may be made without departing in any way from the spirit of the present invention.

Without further analysis, the foregoing will so fully reveal the gist of the present invention that others can, by applying current knowledge, readily adapt it for various applications without omitting features that, from the standpoint of prior art, fairly constitute essential characteristics of the generic or specific aspects of this invention.

We claim:

1. A method of making a highly uniform, low-stress, large-volume single crystal, said method comprising the steps of:
a) growing a single crystal from a melt;
b) cooling the single crystal; and
c) subsequently tempering the single crystal;
wherein said cooling of said single crystal after said growing occurs in a temperature range between 1300° C. and 1050° C. with a cooling rate of at least 10 K/h.

2. The method as defined in claim 1, wherein the single crystal is not heated again to a temperature above 1100° C. after said cooling.

3. The method as defined in claim 1, wherein the single crystal is cooled with a cooling rate of less than 10 K/h in a temperature range under 1050° C. after crystallizing.

4. The method as defined in claim 1, wherein the single crystal is cooled with a cooling rate of less than 5 K/h in a temperature range under 1050° C. after crystallizing.

5. The method as defined in claim 1, wherein said tempering includes heating of the single crystal to a tempering temperature between 1050° C. and 1150° C.

6. The method as defined in claim 1, wherein during said tempering said single crystal is heated at a heating rate between 18 K/h and 0.01 K/h.

7. The method as defined in claim 1, wherein the single crystal is held at a tempering temperature for a time interval of 24 to 240 h.

8. The method as defined in claim 1, wherein the single crystal is cooled at a cooling rate between 0.1 and 1.5 K/h until at a temperature of 800° C. after the tempering.

9. The method as defined in claim 1, wherein the single crystal is cooled at a cooling rate of 0.3 to 3 K/h in a temperature range under 800° C. after the tempering.

10. The method as defined in claim 1, wherein the single crystal is grown from a starting material, which has an oxygen content of less than or equal to 3 ppm and/or a total content of transition metals of less than or equal to 1 ppm.

11. The method as defined in claim 1, wherein the growing, cooling and tempering of the single crystal are performed in the presence of a scavenger and wherein said scavenger is selected from the group consisting of SnF₂, PbF₂, ZnF₂ and XeF₂.

12. The method as defined in claim 1, wherein the growing, cooling and tempering of the single crystal are performed in the presence of a gaseous scavenger and wherein said gaseous scavenger is selected from the group consisting of fluorine gas, mixtures of fluorine gas and inert gas, fluorocarbon gas, mixtures of fluorocarbon gas and inert gas, fluorohydrocarbon gas and mixtures of fluorohydrocarbon gas and inert gas.

13. The method as defined in claim 1, wherein said single crystal consists of calcium fluoride.

14. A single crystal obtainable by a method as defined in one of claims 1 to 13, and wherein the single crystal has a free dislocation density of less than or equal to 2.5×10³/cm³; a small-angle-grain boundaries surface area of less than 2 cm²/cm³; a tilting angle between neighboring grains of less than or equal to 100 arc-sec; a tilting angle between random grains of less than or equal to 8 angular minutes; an index of refraction uniformity for a disk or slab of less than or equal to 1.2×10⁻⁸ after deducting 36 first Zernike coefficients; an average value of stress birefringence of a disk or slab in a 111-direction less than or equal to 0.4 nm/cm and in the 100-direction of less than or equal to 0.7 nm/cm and/or a maximum scattering TS less than or equal to 2×10⁴ according to ISO 13696.

15. The single crystal as defined in claim 14, and consisting essentially of CaF₂.

16. A single crystal having a free dislocation density of less than or equal to 2.5×10³/cm³; a small-angle-grain boundaries surface area of less than 2 cm²/cm³; a tilting angle between neighboring grains of less than or equal to 100 arc-sec; a tilting angle between random grains of less than or equal to 8 angular minutes; an index of refraction uniformity for a disk or slab of less than or equal to 1.2×10⁻⁸ after deducting 36 first Zernike coefficients; an average value of stress birefringence of a disk or slab in a 111-direction less than or equal to 0.4 nm/cm and in the 100-direction of less than or equal to 0.7 nm/cm and/or a maximum scattering (TS) less than or equal to 2×10⁴ according to ISO 13696.

17. The single crystal as defined in claim 16, and consisting essentially of CaF₂.

18. The single crystal as defined in claim 16, and made by a method comprising the steps of:
a) growing a single crystal from a melt;
b) cooling the single crystal; and
c) subsequently tempering the single crystal;
wherein said cooling of said single crystal after said growing occurs in a temperature range between 1300° C. and 1050° C. with a cooling rate of at least 10 K/h.

19. A lens, prism, light-conducting rod, optical component for DUV photo-lithography, stepper or excimer laser comprising a single crystal, wherein said single crystal is obtainable by a method comprising the steps of:
a) growing a single crystal from a melt;
b) cooling the single crystal; and
c) subsequently tempering the single crystal;
wherein said cooling of said single crystal after said growing occurs in a temperature range between 1300° C. and 1050° C. with a cooling rate of at least 10 K/h; and
wherein said single crystal has a free dislocation density of less than .or equal to 2.5×10³/cm³; a small-angle-grain boundaries surface area of less than 2 cm²/cm³; a tilting angle between neighboring grains of less than or equal to 100 arc-sec; a tilting angle between random grains of less than or equal to 8 angular minutes; an index of refraction uniformity of less than or equal to 1.2×10⁻⁸ for a disk or slab after deducting 36 first Zernike coefficients; an average value of stress birefringence of a disk or slab in a 111-direction less than or equal to 0.4 nm/cm and in the 100-direction of less than or equal to 0.7 nm/cm and/or a maximum scattering (TS) less than or equal to 2×10⁴ according to ISO 13696.

20. A computer chip, integrated circuit or electronic unit containing said computer chip or said integrated circuit, which contain at least one of said lens, prism, light-conducting rod, optical component for DUV photolithography, stepper and excimer laser as defined in claim 19.
